(19) United States
(12) Patent Application Publication
(10) Pub. No.: US 2023/0083321 A1
(43) Pub. Date: Mar. 16, 2023

(54) Voltage Current Conversion Device

(71) Applicant: Nippon Telegraph and Telephone Corporation, Tokyo (JP)

(72) Inventors: Masayuki Hashisaka, Musashino-shi, Tokyo (JP); Koji Muraki, Musashino-shi, Tokyo (JP); Takafumi Akiho, Musashino-shi, Tokyo (JP)

(21) Appl. No.: 17/907,870

(22) PCT Filed: Mar. 18, 2020
(86) PCT No.: PCT/JP2020/012149

§ 371 Date: Aug. 29, 2022

(51) Int. Cl. H02M 1/00; H02M 1/32

(52) U.S. Cl. CPC H02M 1/0087; H02M 1/0009; H02M 1/327; H01L 29/778

(57) ABSTRACT

FETs used in a conventional current-to-voltage converter lack current-to-voltage conversion efficiency and have a narrow operating frequency range when operated at cryogenic temperatures, and it is difficult to sensitively measure current. A desired low-temperature environment cannot be realized either due to power consumption in the current-to-voltage converter. A current-to-voltage converter is provided that sensitively measures small currents even in extremely low-temperature conditions. The current-to-voltage converter of the present disclosure uses elements specifically optimized for low-temperature operation (e.g., HEMTs) as electronic elements for current-to-voltage conversion. This configuration realizes significantly more excellent current-to-voltage conversion characteristics than those of the conventional technique even when the current-to-voltage converter is operated at a low temperature of 150K or less or in cryogenic temperature conditions close to absolute zero.

### TECHNICAL FIELD

The present invention relates to an electronic circuit that converts current to voltage.

### BACKGROUND ART

It is known that in order to measure the current, a target current is converted to a voltage and is measured using a voltmeter. To accurately read a small current, it is necessary to convert the current to a voltage using a low-noise electronic circuit. In order to realize this, a method of reducing thermal noise by using a current-to-voltage converter at a low temperature is used. For current signals in the ultra-long to short wave band (1 kHz to 30 MHz), a current-to-voltage converter using low-power field-effect transistors (FETs) that operate at low temperatures has been reported (NPL 1).

FIG. 1 shows a schematic configuration of a current-to-voltage conversion circuit of a conventional current-to-voltage converter (NPL 1). In a current-to-voltage conversion circuit 10, a terminal (current source) from which a target current to be measured flows is connected to an input terminal 11, and a converted voltage corresponding to the target current is measured at an output terminal 14. Current-to-voltage conversion is realized by amplifying signals using four FETs (H1 to H4) and feeding back a source output signal of H4 at the final stage to a gate of H1 on the input side. The conventional current-to-voltage conversion circuit uses generally available FETs that operate at room temperature. For example, the current-to-voltage converter of NPL 1 uses pseudomorphic high electron mobility transistors (HEMT: High Electron Mobility Transistors).

### CITATION LIST

### Non Patent Literature

Hashisaka et. al., “Cross-correlation measurement of quantum shot noise using homemade transimpedance amplifiers”, 2014, Rev. Sci. Instrum. 85, 054704

PAM-XIAMEN GaAs HEMT Epi wafer product catalog page, [online], retrieved on Mar. 6, 2020, Internet <URL: https://www.powerwaywafer.com/gaas-hemt-epi-wafer.html

### SUMMARY OF THE INVENTION

### Technical Problem

However, the open-loop gain of a signal amplification unit is not sufficient in the conventional current-to-voltage converter using FETs capable of operating at room temperature. Very small signals are measured in a current-to-voltage converter when, for example, measuring cosmic rays, quantum device signals, or “quantum fluctuations” of a current, or observing physical phenomena at low temperatures. In order to measure such small currents, it is necessary to operate the current-to-voltage converter at a very low temperature, at least at the temperature of liquid nitrogen (77K) or less, and even closer to absolute zero. The FETs used in the conventional technology current-to-voltage converter are based on the premise of operating at room and low temperatures. For this reason, even if these FETs are operated at cryogenic temperatures, the current-to-voltage conversion efficiency is insufficient, the operating frequency range is limited, and sensitive current measurement is difficult. Moreover, a desired low-temperature environment cannot be realized with a cooling system due to power consumption of the current-to-voltage converter when used in a cooled state.

The present invention has been made in view of the foregoing problems, and an object of the invention is to provide a means for sensitively measuring small currents in extremely low-temperature conditions.

### Means for Solving the Problem

To achieve the above object, one embodiment of the present invention is a current-to-voltage converter including: an amplification unit having at least three stages each including an electronic element and configured to convert a target current, which is fed to a first stage, to a voltage while feeding back an output signal of a final stage to the first stage; and a buffer unit connected to the amplification unit and configured to output the converted voltage, wherein the electronic element is a field-effect transistor (FET) adapted to operation at a temperature of 150 K or less.

### Effects of the Invention

A means for sensitively measuring small currents in extremely low-temperature conditions is provided.

### BRIEF DESCRIPTION OF DRAWINGS

FIG. 1 shows a schematic configuration of a conventional current-to-voltage conversion circuit.

FIG. 2 illustrates a configuration for low-temperature operation of a current-to-voltage converter.

FIG. 3 shows a configuration of a current-to-voltage conversion circuit of a current-to-voltage converter of the present disclosure.

FIG. 4 shows frequency characteristics of current-to-voltage conversion efficiency compared to those of the conventional technique.

FIG. 5 shows characteristics of an FET specialized for low-temperature operation that is used in the current-to-voltage converter.

FIG. 6 illustrates configuration characteristics of the FET specialized for low-temperature operation.

### DESCRIPTION OF EMBODIMENTS

The following disclosure relates to a current-to-voltage converter that sensitively measures small currents even in extremely low-temperature conditions. A current-to-voltage converter of the present disclosure uses elements specifically optimized for low-temperature operation (e.g., HEMTs) as electronic elements for current-to-voltage conversion. This configuration makes it possible to achieve significantly more excellent current-to-voltage conversion characteristic than those of the conventional technique even if the current-to-voltage converter is operated at a low temperature of 150 K or less or in cryogenic temperature conditions close to absolute zero.

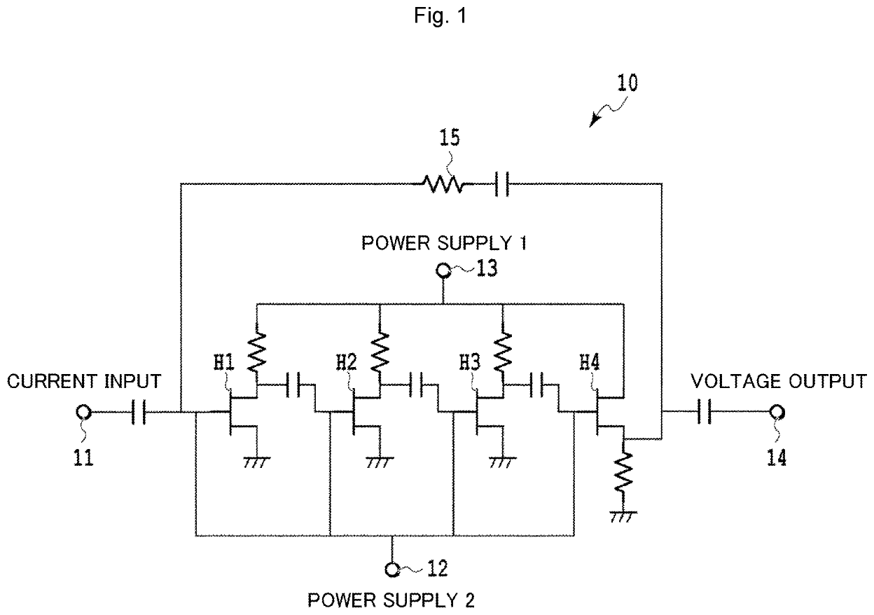

Referring to FIG. 1 again, the FETs H1 to H4 used in a current-to-voltage conversion circuit 10 are based on the premise of also operating at room temperature. In general, electronic elements have different operating performance depending on the temperature at which they are used. In the case of a current-to-voltage conversion circuit, all the characteristics and operating requirements such as power supply voltage to be fed to the FETs, conversion efficiency, and noise characteristics vary with temperature. For example, the pseudomorphic FETs of the current-to-voltage converter disclosed in NPL 1 are generally available electronic devices, and operate at both room temperature and low temperatures. This is because the ability to operate at room temperature in a test of electronic elements makes it possible to first perform characterization at room temperature and then selectively and optionally perform costly low-temperature evaluation. Therefore, pseudomorphic FETs that can be used at both room and low temperatures are generally available, and even elements that are commercially available for low-temperature use generally display operating power supply voltages and characteristics for both room and low temperatures.

However, the current-to-voltage conversion characteristics of FETs operating at both room and low temperatures are inadequate in situations where the FETs are cooled to near absolute zero to measure small currents, such as cosmic rays, quantum device signals, or “quantum fluctuations” of a current. The open-loop gain G_{OP} of the signal amplification units (FETs) of the current-to-voltage conversion circuit becomes small at low temperatures, causing strong limitations on the current-to-voltage conversion efficiency (A=V/A, where V: output voltage, I: input current) and the operating frequency range. The accuracy of current measurement in a current-to-voltage conversion circuit such as the one shown in FIG. 1 is proportional to the current-to-voltage conversion efficiency of the FETs. To realize measurements for smaller currents, it is necessary to increase the open-loop gain of the signal amplification units (H1 to H4) and improve the current-to-voltage conversion efficiency.

The inventors thought that if the electronic elements used in the conventional current-to-voltage converter were specialized for operation and performance at low temperatures, more favorable low-noise characteristics could be obtained in low-temperature conditions. In terms of efficiency of testing during mass production of electronic elements and ease of use and evaluation at room temperature, there are significant advantages for both suppliers and users in fabricating electronic elements that operate at room and low temperatures. This is because the performance at low temperatures can be estimated by the performance and a test at room temperature, and the test at room temperature can therefore be substituted. Above all, the evaluation at room temperature is simple and low cost. The inventors thought that even if the advantage that testing and operation can be done at room temperature is abandoned, there is a possibility that the ultimate low-noise measurement is obtained if the electronic elements are specialized for operation and performance at low temperatures.

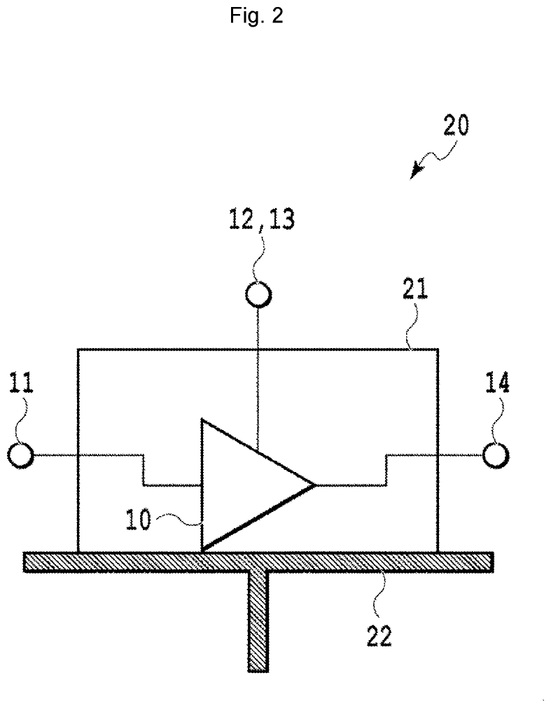

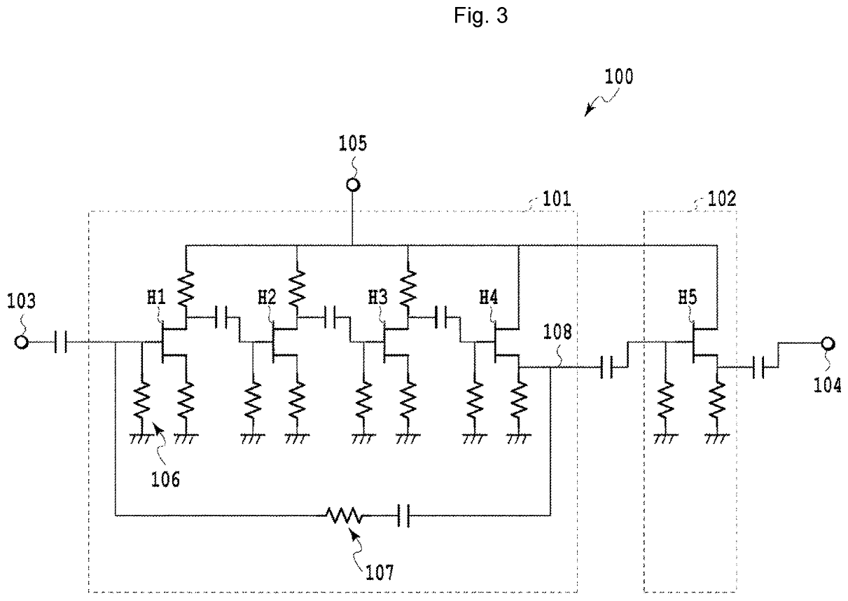

FIG. 2 illustrates a configuration for a low-temperature operation of a current-to-voltage converter. Another problem with the conventional current-to-voltage converter is the limitation imposed by the capability of the cooling device in the case of using the current-to-voltage converter in low-temperature conditions. In a current-to-voltage converter 20 in FIG. 2, the current-to-voltage conversion circuit 10 shown in FIG. 1 is arranged within a cooling device, which has, for example, a cooling stage 22 and a case 21 of the cooling stage 22. Although the current-to-voltage conversion circuit 10 is symbolically shown by a symbol of an amplifier, in practice, the current-to-voltage conversion circuit 10 may be a package of the plurality of elements (FETs) shown in FIG. 1 and other elements on a circuit board. Furthermore, the current-to-voltage conversion circuit 10 may be a circuit in which this package is contained in a case made of oxygen-free copper or the like, and this case is arranged on the stage 22. A current input terminal 11, a voltage output terminal 14, and two power supply terminals 12 and 13 are taken out from inside the case 21.

The cooling device can take various forms, but one example is a dilution refrigerator. The dilution refrigerator is a cylindrical can having a diameter of 0.5 to 1 m×a height of about 2 m that contains the above-described current-to-voltage conversion circuit 10 and has a mechanism for circulating helium inside the can. The dilution refrigerator may also include external mechanisms such as a pump and a compressor for helium circulation, which are not shown in FIG. 2. Examples of other types of available cooling devices and cooling temperatures include, for example: a dilution refrigerator: about 10 mK to 1 K, a 3He refrigerator: about 300 mK, a 4He refrigerator: about 1.5K, liquid helium: 4.2 K, liquid nitrogen: 77 K, and a refrigerant-free pulse tube refrigerator: 1.5 K to 300 K. Note that the form of the case and cooling stage varies depending on the type of cooling device.

In order to sensitively measure small currents using a current-to-voltage converter circuit, it is assumed to be used in combination with a cooling device as shown in FIG. 2. Since the aforementioned cooling device has a finite cooling capacity, it is necessary to keep the power consumption of the current-to-voltage converter 10 arranged inside low. Even with the most advanced cooling device, it is difficult to maintain cryogenic temperatures if electronic circuits with large power consumption are housed inside.

“Cooling capacity” is known as an important indicator of a cooling device, and indicates how many watts or less of heat generation in the cooling device is required to maintain a certain temperature. In other words, it means the maximum amount of heat generated that can be tolerated with respect to a cooling target in the cooling device. For example, in the case of a cooling device (dilution refrigerator) for achieving a low temperature of about milli-Kelvin, the typical cooling capacity is about 500 μW at 100 mK in the most advanced device. This means that in order to maintain a low temperature of 100 mK, the power consumption generated in the cooling device needs to be or 500 μW or less. Therefore, the indicator “cooling capacity” may be higher as the temperature set by the cooling device is higher. For example, if the temperature is maintained at 200 mK, the heat generated by a cooling object, i.e., the power consumption in the cooling system may be up to twice as large as that in the case of 100 mK. It is known to be 3 to 5 times higher, in practice, in the case of the dilution refrigerator.

In general, the lower the temperature of an electronic circuit, it is possible to further suppress thermal noise and achieve low noise. It is also advantageous to use a current-to-voltage converter in an environment at as low a temperature as possible for the realization of the ultimate low-noise measurements. Accordingly, it is necessary to suppress the power consumption of the current-to-voltage converter as much as possible to a small level relative to the index “cooling capacity” of the cooling device. The conventional current-to-voltage converter described in NPL 1 has a power consumption of 1.5 mW and can only be used at a temperature of 500 mK or more even with the most advanced dilution refrigerator. Therefore, in order to reduce the load on the cooling device, it is necessary to further reduce the power consumption of the current-to-voltage converter.

The current-to-voltage converter of the present disclosure simultaneously solves the aforementioned problems of insufficient open-loop gain during low-temperature operation and limited capacity of the cooling device by using electronic elements (FETs) specifically configured for low-temperature operation and by the unique configuration of the current-to-voltage conversion circuit.

FIG. 3 shows a configuration of a current-to-voltage conversion circuit in a current-to-voltage converter of the present disclosure. The current-to-voltage conversion circuit 100 is roughly divided into a current-to-voltage conversion unit 101 and an output-stage source follower unit 102. The current-to-voltage conversion unit 101 is similar to that in FIG. 1 in its basic amplifier configuration, and includes three FETs (H1 to H3) that constitute common source voltage amplifier stages and a final output stage FET (H4) that is a source follower. An output voltage 108 from the source of H4 is fed back to the gate of H1 via a feedback resistor 107. The gates of the FETs are set to a ground potential by gate resistors 106, and each FET is self-biased by a source resistor using power from a single power supply terminal 105. The current-to-voltage conversion unit 101 functions as an amplification unit that converts a target current, which is fed to the first stage, to a voltage while feeding back an output signal of the final stage to the first stage.

The output-stage source follower unit 102 is not included in the conventional current-to-voltage conversion circuit 10 in FIG. 1. That is, in the current-to-voltage conversion circuit 100 of the present disclosure, the source follower FET (H5) after the final stage prevents the frequency characteristics of the current-to-voltage conversion circuit 100 from deteriorating due to stray capacitance of a coaxial cable for extracting the voltage output from the cooling system when the cable is connected to the downstream side of an output voltage terminal 104. In general, a source follower at an output of a circuit is used to reduce output impedance of the circuit and avoid variations in its own operation that it undergoes due to the connection to the next stage circuit.

When measuring a current at room temperature at which current consumption is not limited, a large current can be applied to the source follower (H4) of the current-to-voltage conversion unit 101. However, it was found that a single-stage source follower was not sufficient when a current-to-voltage converter is used at cryogenic temperatures based on the premise of the use of a cooling device. There is a limit to the current consumption that can be allocated to the source follower FET, and the output impedance of the source follower cannot be reduced sufficiently. Therefore, the output-stage source follower unit 102 is further provided, making it possible to prevent deterioration of the frequency characteristics in the current-to-voltage conversion characteristics due to the cable stray capacitance. By using later-described low-current FETs specialized for low-temperature operation, which will be discussed later, the increase in the number of amplification stages (from 4 to 5) can be compensated for, and smaller power consumption can also be achieved in the entire current-to-voltage conversion circuit. As a result, the load on the cooling device in cryogenic measurement is reduced, while at the same time wide-band small current measurement is realized. Accordingly, the output-stage source follower unit 102 is connected to the amplification unit, and functions as a buffer unit that outputs the voltage obtained by converting the target current.

Characteristics of the current-to-voltage converter of this disclosure lie in that FETs with a configuration specialized for low-temperature operation are used as the FETs (H1 to H5) of the current-to-voltage conversion circuit in FIG. 3. Examples of FETs specialized for low-temperature operation include GaAs-based HEMTs, specifically n-AlₓGa₁₋ₓAs/GaAs HEMTs (x=0.25 to 0.4) and GaAs quantum well HEMTs. GaAs-based HEMTs exhibit high electron mobility at low temperatures, and therefore operate as broadband and low-noise FETs and facilitate fabrication of elements with large transconductance at low temperatures.

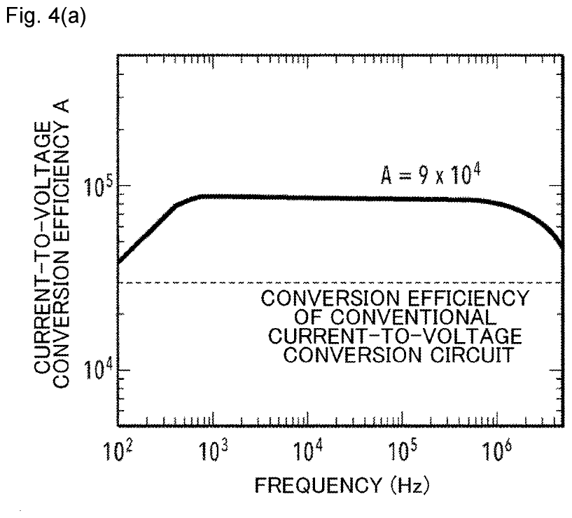

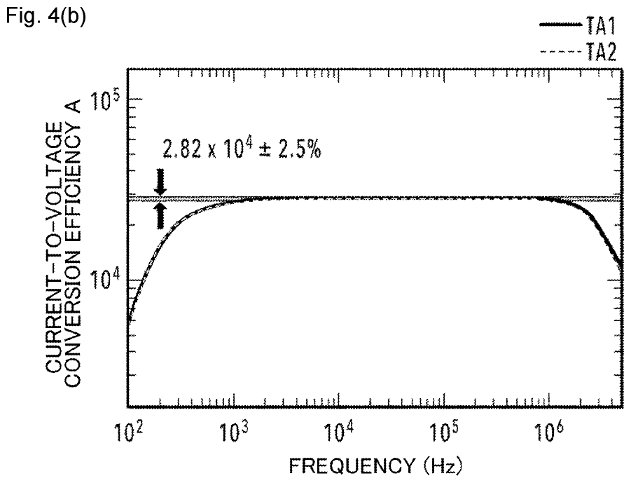

FIG. 4 shows frequency characteristics of the current-to-voltage conversion efficiency of the current-to-voltage converter of the present disclosure in comparison to the conventional technique. FIG. 4(b) shows the current-to-voltage conversion efficiency at 4K in the case where the conventional current-to-voltage conversion circuit 10 shown in FIG. 1 uses FETs capable of operating at room and low temperatures. Specifically, AVAGO ATF35143, which is generally used in low temperature experiments, was used. The figure shows the conversion efficiency A(V/A) in the case where the frequency band with which the deviation of the current-to-voltage conversion efficiency A is ±2.5% is set to be in the range of 1 k to 1 MHz by adjusting a feedback resistor. Both two samples (TA1 and TA2) of the FETs capable of operating at room and low temperatures exhibit conversion efficiency A of only about 3×10⁴ V/A.

Meanwhile, FIG. 4(a) shows the current-to-voltage conversion efficiency at 4 K in the case where the current-to-voltage conversion circuit 100 of the present disclosure shown in FIG. 3 uses FETs specialized for low-temperature operation. Specifically, GaAs-AlGaAs HEMTs with a channel width of 3 mm, a gate length of 4 μm, a gate metal electrode thickness of 190 nm, and a distance from the gate metal electrode to the channel (gate insulating layer thickness) of 55 nm, are used. FIG. 4(a) shows the conversion efficiency A (V/A) in the case where the frequency band with which the deviation of the current-to-voltage conversion efficiency A is ±2.5% is set to be in the range of 1 k to 1 MHz by adjusting the feedback resistor 107, similarly to FIG. 4(b). The current-to-voltage conversion efficiency A at this time is 9×10⁴ V/A. The aforementioned current-to-voltage conversion efficiency of the conventional technique shown in FIG. 4(b) is also indicated by a dotted line. It can be confirmed that the current-to-voltage conversion efficiency is significantly improved by using the FETs specialized for low-temperature operation.

In the case of the configuration using the conventional FETs capable of operating at room and low temperatures shown in FIG. 4(b), the total gain determined by a common source amplifier circuit that includes H1 to H3, namely the open-loop gain G_{OP} at 4 K is about 350. In contrast, the open-loop gain G_{OP} at 4 K in the case of using the FETs specialized for low-temperature operation shown in FIG. 4(a) was about 5000 or more. The current-to-voltage conversion efficiency A can be increased about three times with the current-to-voltage converter of the present disclosure whose gain is adjusted so as to have the same operating frequency band as that of the conventional device. Meanwhile, the power consumption in the current-to-voltage conversion circuit can be almost halved from 1.5 mA in the conventional technique to 0.75 mW. It can be confirmed that the current-to-voltage conversion efficiency is significantly improved, while the power consumption can be halved.

Accordingly, the current-to-voltage converter of the present disclosure can be implemented as a device that includes the amplification unit 101 that has at least three stages each including an electronic element, and converts a target current, which is fed to the first stage, to a voltage while feeding back the output signal of the final stage to the first stage, and the buffer unit 102 that is connected to the amplification unit and outputs the converted voltage. Here, the electronic element is a field-effect transistor (FET) adapted for operation at temperatures of 150 K or less. The amplification unit may include four common source voltage amplifier stages with the final stage constituting a source follower, and the buffer unit may be a source follower that includes the electronic element.

Here, a description will be given to more specific comparison of characteristics between the FET that operates at both room and low temperatures used in the conventional current-to-voltage converter and the FET specialized for low-temperature operation used in the current-to-voltage converter of the present disclosure. The HEMTs (FETs) used in the current-to-voltage conversion circuit 100 shown in FIG. 3 have a GaAs-AlGaAs modulation-doped superlattice structure. Pseudomorphic HEMTs and InP-based HEMTs can also be used. These HEMTs can operate at low temperatures and have excellent noise characteristics.

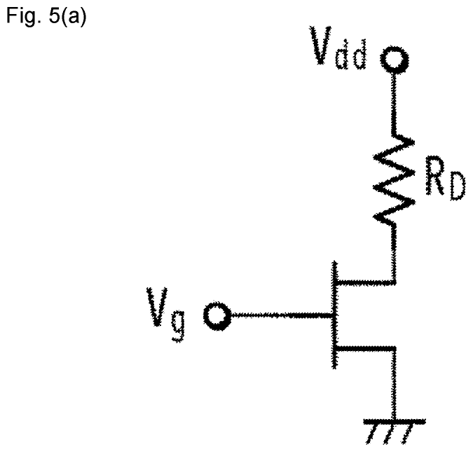

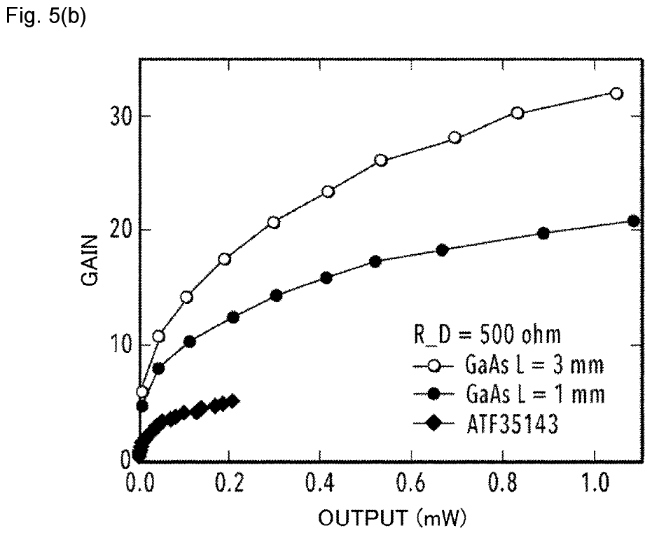

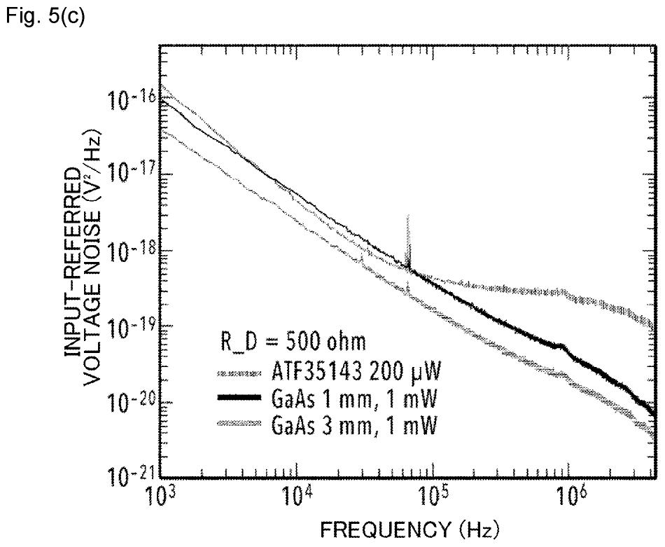

FIG. 5 shows an example of the characteristics of the FET specialized for low-temperature operation used in the current-to-voltage converter of the present disclosure. FIG. 5(a) shows a circuit configuration for obtaining the characteristics of the FET, FIG. 5(b) shows the relationships between power consumption and gain, and FIG. 5(c) shows input-referred voltage noise spectra. Both show the comparison at a temperature of 4.2K (liquid helium temperature) between the GaAs-AlGaAs HEMT used in the current-to-voltage converter of the present disclosure and a commercially available pseudomorphic HEMT (AVAGO ATF35143) that is used in the conventional current-to-voltage converter and is often used in other low-temperature experiments. FIGS. 5(b) and 5(c) show results obtained with GaAs-AlGaAs HEMTs with channel widths of 1 mm and 3 mm are used. Note that the aforementioned current-to-voltage conversion efficiency A shown in FIG. 4(a) is exhibited by a GaAs-AlGaAs HEMT with a channel width of 3 mm.

FIG. 5(b) shows the relationships between gain and power consumption in the case where the drain resistance R_ D=500 Ω. Since this pseudomorphic HEMT typically operates unstably when power consumption is 0.2 mW or more, FIG. 5(b) shows the results with up to 0.2 mW. Compared with the FET that operates at both room and low temperatures, the GaAs-AlGaAs HEMTs specialized for low-temperature operation obtain significantly greater gain with the same power consumption. Further, the total power consumption in the current-to-voltage conversion circuit that includes five HEMT is kept at 1 mW or less both when the channel width is 1 mm and when it is 3 mm. Further, the power consumption is reduced to ⅔ of the power consumption of 1.5 mW in NPL 1.

Referring to FIG. 5(c), the input-referred noise (noise characteristics) of the GaAs-AlGaAs HEMT with a channel width of 3 mm falls below that of the pseudomorphic HEMT over the entire band measured. Particularly, it can be understood that low noise characteristics of the GaAs-AlGaAs HEMT are significant in the MHz band. From FIG. 5(c), the input-referred noise at 1 MHz in the case where the GaAs-AlGaAs HEMT is used with a power consumption of 1 mW at a temperature of 4.2 K is kept at 10⁻¹⁹ V²/Hz or less.

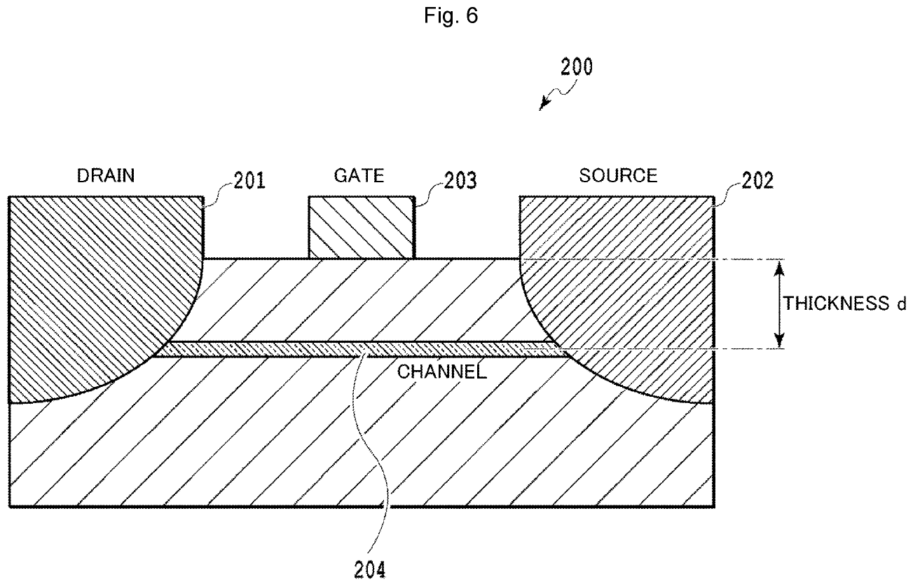

FIG. 6 illustrates configuration characteristics of the FET specialized for low-temperature operation. FIG. 6 shows a cross-sectional configuration 200 of a channel portion of the HEMT, where a channel 204 is formed between a drain 201 and a source 202. A current flowing through the channel 204 is controlled by the gate 203. In the case of a HEMT that operates at room temperature, the thickness d of the gate insulating layer needs to be sufficiently large in order to reduce leakage current between the channel and the gate. Accordingly, the HEMT capable of operating at both room and low temperatures usually has an insulating layer thickness d of 100 nm or more. Meanwhile, the larger the thickness d, the smaller the response to a change in gate voltage, and the lower the sensitivity to an input signal to the gate.

In the GaAs-AlGaAs HEMT with a channel width of 3 mm specialized for low-temperature operation used in the current-to-voltage converter of the present disclosure, the insulating layer thickness d at a temperature 4 K is set to be 100 nm or less; more specifically, 55 nm. Doping to the AlGaAs layer is performed twice at a concentration of 6×10¹¹ cm⁻² by the delta-doping method. This is equivalent to a channel carrier density of 4×10¹¹ cm⁻². When this HEMT is used as an amplifier element, the electrical resistance between the gate and the channel is 200 kΩ/mm in actual measurement at room temperature. Thus, this HEMT cannot be used due to its large leakage behavior. In contrast, for example, at liquid helium temperature (4.2 K), the electrical resistance between the gate and the channel is 1 GΩ/mm or more, and thus the leakage current can be ignored. By abandoning normal operation at room temperature and using a HEMT specialized for low-temperature operation, the current detection sensitivity of the HEMT serving as the current-to-voltage conversion circuit for cryogenic temperature can be greatly improved.

In room-temperature operation, it is important in general to suppress leakage between the gate and the channel in HEMTs. In GaAs-AlGaAs HEMTs, the gate and the channel are naturally insulated since the Schottky barrier is formed. However, the insulating layer needs to be made thick to some extent. A configuration of a commonly available GaAs-AlGaAs HEMT is disclosed, for example, in NPL 2, where the thickness of the insulating layer is 210 nm, although the amount of doping is not mentioned. Although different materials require different insulating layer thicknesses, a thickness of 100 nm or more is generally considered to be common in the case of GaAs-AlGaAs. In the current-to-voltage converter of the present disclosure, current-to-voltage conversion characteristics that are significantly superior to those of the conventional technique is achieved by adopting a configuration specialized for low-temperature operation with a gate insulating layer of 100 nm or less in thickness, which cannot be selected for normal-temperature operation.

Here, the configuration of the HEMT specialized for low-temperature operation will be examined further. In a current-to-voltage conversion circuit, the shorter the distance between the gate and the channel and the thinner the gate insulating layer, the better in order to increase the current detection sensitivity, as mentioned above. Further, the larger the amount of change in channel current (transconductance) with respect to the gate voltage, the better. Thus, the larger the amount of doping, the higher the current detection sensitivity.

However, the two conditions of the gate insulating layer thickness and the doping amount can only be optimized within the range where no carrier is generated in the gate insulating layer. It is known that beyond this range, a gate leakage current occurs at room temperature, and parallel conduction reduces mobility and degrades HEMT characteristics. If carriers are generated in the gate insulating layer of the HEMT and a gate leakage current flows, the HEMT cannot be used as a current-to-voltage conversion circuit, or even as an electronic element as it does not have the basic operation and performance at room temperature.

In order to ensure the aforementioned basic operation as an electronic element, most of the commercially available HEMTs have a barrier layer, which is a part of the gate insulating layer, with a thickness of 100 nm or more, for example. According to NPL 2, the barrier layer is 180 nm, and the total gate thickness of the three-layer structure is 210 nm. A HEMT with a configuration having such a thick gate insulating layer is a barrier to highly sensitive measurements conducted at low temperatures.

As a result of using HEMTs with a gate insulating layer thickness of 55 nm to which delta doping (6×10¹¹ cm⁻²) was performed twice in the current-to-voltage conversion circuit of the present disclosure, a current-to-voltage conversion circuit was prototyped and excellent noise performance was confirmed. These HEMTs have a gate resistor with an electrical resistance of 200 kΩ/mm in actual measurement at room temperature, and cannot be used as HEMTs at room temperature due to leakage current. However, as already described with reference to FIGS. 4 and 5, high sensitivity and lower power consumption can be achieved compared to the conventional current current-to-voltage converter. The current-to-voltage converter of the present disclosure uses HEMTs specialized for low-temperature operation as described above. As a possible guide for a HEMT configuration specialized for low-temperature operation, the gate insulating layer thickness is 100 nm or less, preferably 55 nm or less, and is more than equivalent to a channel carrier density of 4×10¹¹ cm⁻².

As described above in detail, small current measurement with excellent sensitive can be realized in extremely low-temperature conditions by the current-to-voltage converter of the present disclosure. Industrial Applicability

### INDUSTRIAL APPLICABILITY

The present invention can be used in highly sensitive measurement of small currents.

### REFERENCE SIGNS LIST

10, 100 Current-to-voltage conversion circuit
11, 103 Current input terminal
12, 13, 105 Power supply terminal
14, 104 Voltage output terminal
15, 107 Feedback resistor
20 Current-to-voltage converter
21 Case
22 Cooling stage
108 Drain output voltage
200 HEMT cross section
201 Drain
202 Source
203 Gate
204 Channel

1. A current-to-voltage converter comprising:
an amplification unit having at least three stages each including an electronic element and configured to convert a target current, which is fed to a first stage, to a voltage while feeding back an output signal of a final stage to the first stage; and
a buffer unit connected to the amplification unit and configured to output the converted voltage,
wherein the electronic element is a field-effect transistor (FET) adapted to operation at a temperature of 150 K or less.

2. The current-to-voltage converter according to claim 1, wherein
the amplification unit has four common source voltage amplifier stages, and the final stage constitutes a source follower, and
the buffer unit is a source follower that includes the electronic element.

3. The current-to-voltage converter according to claim 1, wherein
the FET is a high electron mobility transistor (HEMT), and has a gate insulating layer is 100 nm or less.

4. The current-to-voltage converter according to claim 1, wherein
the FET is a high electron mobility transistor (HEMT), and has a 1-MHz input-referred noise of 10⁻¹⁹ V²/Hz or less when used at a temperature of 4.2 K with a power consumption of 1 mW.

5. The current-to-voltage converter according to claim 1, wherein
the FET is a high electron mobility transistor (HEMT), and a doping amount in a gate insulating layer is equivalent to a channel carrier density of 4×10¹¹ cm⁻² or more.

6. The current-to-voltage converter according to claim 3, wherein
the HEMT is a HEMT with a GaAs-AlGaAs modulation-doped superlattice structure, a pseudomorphic HEMT, or an InP-based HEMT.

7. A small current measurement device comprising the current-to-voltage converter according to claim 1, the current-to-voltage converter being provided within a cooling device.

8. The current-to-voltage converter according to claim 2, wherein
the FET is a high electron mobility transistor (HEMT), and has a gate insulating layer is 100 nm or less.

9. The current-to-voltage converter according to claim 2, wherein
the FET is a high electron mobility transistor (HEMT), and has a 1-MHz input-referred noise of 10⁻¹⁹ V²/Hz or less when used at a temperature of 4.2 K with a power consumption of 1 mW.

10. The current-to-voltage converter according to claim 2, wherein
the FET is a high electron mobility transistor (HEMT), and a doping amount in a gate insulating layer is equivalent to a channel carrier density of 4×10¹¹ cm⁻² or more.

11. The current-to-voltage converter according to claim 4, wherein
the HEMT is a HEMT with a GaAs-AlGaAs modulation-doped superlattice structure, a pseudomorphic HEMT, or an InP-based HEMT.

12. The current-to-voltage converter according to claim 5, wherein
the HEMT is a HEMT with a GaAs-AlGaAs modulation-doped superlattice structure, a pseudomorphic HEMT, or an InP-based HEMT.

13. A small current measurement device comprising the current-to-voltage converter according to claim 2, the current-to-voltage converter being provided within a cooling device.

14. A small current measurement device comprising the current-to-voltage converter according to claim 3, the current-to-voltage converter being provided within a cooling device.

15. A small current measurement device comprising the current-to-voltage converter according to claim 4, the current-to-voltage converter being provided within a cooling device.

16. A small current measurement device comprising the current-to-voltage converter according to claim 5, the current-to-voltage converter being provided within a cooling device.

17. A small current measurement device comprising the current-to-voltage converter according to claim 6, the current-to-voltage converter being provided within a cooling device.
